(19) United States
(12) Patent Application Publication
(10) Pub. No.: US 2025/0185476 A1
(43) Pub. Date: Jun. 5, 2025

(54) OLED DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventor: Liangfen ZHANG, Shenzhen (CN)

(21) Appl. No.: 17/773,049

(22) PCT Filed: Mar. 28, 2022
(86) PCT No.: PCT/CN2022/083242

§ 371 Date: Jan. 27, 2025

(30) Foreign Application Priority Data
Mar. 18, 2022 (CN) 202210272468.0

(51) Int. Cl. H10K 59/131; H10D 86/40; H10D 86/60; H10K 59/12; H10K 59/122; H10K 59/80

(52) U.S. Cl. CPC H10K 59/131; H10D 86/443; H10D 86/481; H10D 86/60; H10K 59/1201; H10K 59/122; H10K 59/8792

(57) ABSTRACT

An OLED display panel and a manufacturing method thereof are provided. In the OLED display panel, the first auxiliary electrode and the second auxiliary electrode arranged at intervals are arranged in the source-drain layer, the third auxiliary electrode is arranged above the first auxiliary electrode and the second auxiliary electrode, and the third auxiliary electrode covers and connects the first auxiliary electrode and the second auxiliary electrode, which can alleviate the problem of uneven display brightness in different regions on the OLED display panel caused by the large impedance of the first cathode.

### BACKGROUND OF INVENTION

### Field of Invention

The present application relates to the field of display technology, and in particular, to an OLED display panel and a manufacturing method thereof.

### Description of Prior Art

With development of semiconductor technology, organic light-emitting diode (OLED) display panels have been widely used due to their advantages of high brightness, low power consumption, fast response time, high definition, and high luminous efficiency.

### SUMMARY OF INVENTION

### Technical Issue

However, a large-sized top-emission OLED display panel will generate different voltage drops (IR Drops) at different positions due to the large resistance of its cathode during operation, resulting in uneven display brightness in different regions of the OLED display panel.

### Solution to Issue

### Technical Solution

Embodiments of the present application provide an organic light-emitting diode (OLED) display panel and a manufacturing method thereof, which can alleviate the problem of uneven display brightness in different regions of the OLED display panel caused by large impedance of a cathode.

In a first aspect, an embodiment of the present application provide an OLED display panel, including:
a thin film transistor (TFT) backplane, wherein a topmost structural layer in the TFT backplane is a source-drain layer, and the source-drain layer includes a source electrode, a drain electrode, a first auxiliary electrode, and a second auxiliary electrode arranged at intervals;
a first conductive layer disposed on the TFT backplane, wherein the first conductive layer includes a third auxiliary electrode, and the third auxiliary electrode covers the first auxiliary electrode and the second auxiliary electrode, and electrically connects the first auxiliary electrode to the second auxiliary electrode;
a passivation layer disposed on the TFT backplane and covering the source-drain layer and the first conductive layer, wherein the passivation layer is provided with a first through hole and a second through hole, the first through hole is defined corresponding to an interval area between the first auxiliary electrode and the second auxiliary electrode, and the second through hole is defined corresponding to the source electrode;
a planarization layer arranged on a side of the passivation layer away from the TFT backplane, wherein a third through hole and a fourth through hole are defined in the planarization layer, the third through hole is communicated with the first through hole, the fourth through hole is communicated with the second through hole, and in a direction from the first auxiliary electrode to the second auxiliary electrode, at least one end of the first through hole that is close to the third auxiliary electrode has a width greater than a width of the third through hole;
an anode disposed on the planarization layer, wherein the anode is electrically connected to the source electrode through the fourth through hole and the second through hole;
a pixel definition layer disposed on the planarization layer, wherein the pixel definition layer is provided with an opening and a sixth through hole, the sixth through hole is arranged corresponding to the third through hole, and the opening exposes an anode;
a first light-emitting layer disposed on the pixel definition layer, wherein a portion of the first light-emitting layer corresponding to the opening covers the anode;
a second light-emitting layer disposed on the third auxiliary electrode;
a first cathode disposed on the first light-emitting layer; and
a second cathode disposed on the second light-emitting layer, wherein the first cathode is connected to the second cathode, and the second cathode covers the second light-emitting layer and is in contact with the third auxiliary electrode.

In some embodiments, the first auxiliary electrode and the second auxiliary electrode are parallel to each other.

In some embodiments, the first auxiliary electrode is not parallel to the second auxiliary electrode.

In some embodiments, the first conductive layer further includes a protective layer spaced apart from the third auxiliary electrode, the protective layer is arranged above the source electrode, and opposite sides of the protective layer are respectively electrically connected to the source electrode and the anode electrode.

In some embodiments, the TFT backplane includes a base substrate, a buffer layer, a semiconductor layer, a gate insulating layer, a gate electrode, an interlayer dielectric layer, and the source-drain layer which are stacked in sequence, wherein the semiconductor layer includes an active layer, the active layer is disposed corresponding to the gate electrode, the active layer includes a channel region and a source electrode and a drain contact region disposed on opposite sides of the channel region, the interlayer dielectric layer is provided with a seventh through hole and an eighth through hole, the source electrode is connected to the source contact region of the active layer through the seventh through hole, and the drain is connected to the drain contact region of the active layer through the eighth through hole.

In some embodiments, the semiconductor layer further includes a first storage capacitor electrode spaced apart from the active layer; and a light-shielding layer is disposed between the base substrate and the buffer layer, the light-shielding layer is disposed corresponding to the active layer and the first storage capacitor electrode, and a storage capacitor is formed between the light-shielding layer and the first storage capacitor electrode.

In some embodiments, a driving TFT area, a light-emitting area, and an auxiliary electrode area are defined on the OLED display panel, wherein the source electrode, the drain electrode, and the gate electrode, the active layer are all arranged in the driving TFT area; the opening of the pixel definition layer and the first storage capacitor electrode are both arranged in the light-emitting area; and the first auxiliary electrode, the second auxiliary electrode, and the third auxiliary electrode are all disposed in the auxiliary electrode region.

In a second aspect, an embodiment of the present application provides a method of manufacturing an organic light-emitting diode (OLED) display panel, including:
providing a thin film transistor (TFT) backplane, wherein a topmost structural layer in the TFT backplane is a source-drain layer, and the source-drain layer includes a source electrode, a drain electrode, a first auxiliary electrode, and a second auxiliary electrode arranged at intervals;
forming a first conductive layer on the TFT backplane, wherein the first conductive layer includes a third auxiliary electrode, and the third auxiliary electrode covers the first auxiliary electrode and the second auxiliary electrode, and electrically connects the first auxiliary electrode to the second auxiliary electrode;
forming a passivation layer on the TFT backplane to cover the source-drain layer and the first conductive layer, and forming a first through hole and a second through hole in the passivation layer, wherein the first through hole is defined corresponding to an interval area between the first auxiliary electrode and the second auxiliary electrode, and the second through hole is defined corresponding to the source electrode;
forming a planarization layer on a side of the passivation layer away from the TFT backplane, and forming a third through hole and a fourth through hole in the planarization layer, wherein the third through hole is communicated with the first through hole, and the fourth through hole is communicated with the second through hole;
forming a photoresist layer on the planarization layer, and forming a fifth through hole in the photoresist layer, wherein the fifth through hole is communicated with the third through hole;
providing an etchant entering the first through hole through the fifth through hole and the third through hole, to etch a portion of the passivation layer around the first through hole, so that an aperture of at least one end of the first through hole that is close to the third auxiliary electrode is enlarged, and in a direction from the first auxiliary electrode to the second auxiliary electrode, the at least one end of the first through hole that is close to the third auxiliary electrode has a width greater than a width of the third through hole;
removing the photoresist layer, and forming an anode on the planarization layer, wherein the anode is electrically connected to the source electrode through the fourth through hole and the second through hole;
forming a pixel definition layer on the planarization layer to cover the anode, and forming an opening and a sixth through hole in the pixel definition layer, wherein the sixth through hole is disposed corresponding to the third through hole, and the opening exposes the anode;
depositing a luminescent material on a side of the TFT backplane on which the pixel defining layer is disposed, wherein the luminescent material deposited on the pixel defining layer forms a first light-emitting layer, the light-emitting material passing through the sixth through hole and the third through hole to deposit on the third auxiliary electrode forms a second light-emitting layer, and a portion of the first light-emitting layer corresponding to the opening covers the anode; and
depositing a conductive material on a side of the TFT backplane on which the first light-emitting layer is disposed, wherein the conductive material deposited on the first light-emitting layer forms a first cathode, the conductive material deposited on the second light-emitting layer forms a second cathode, the first cathode is connected to the second cathode, and the second cathode covers the second light-emitting layer and is in contact with the third auxiliary electrode.

In some embodiments, the first auxiliary electrode and the second auxiliary electrode are parallel to each other.

In some embodiments, the first auxiliary electrode and the second auxiliary electrode are not parallel.

In some embodiments, each of the first auxiliary electrode and the second auxiliary electrode is independently linear, curved, or folded.

In some embodiments, the first conductive layer further includes a protective layer spaced apart from the third auxiliary electrode, the protective layer is arranged above the source electrode, and the protective layer is electrically connected to the source electrode; and

the anode is electrically connected to a side of the protective layer away from the source electrode after the anode is disposed on the planarization layer.

### Beneficial Effect of Invention

### Beneficial Effect

In the OLED display panel provided by an embodiment of the present application, the first auxiliary electrode and the second auxiliary electrode arranged at intervals are arranged in the source-drain layer, and the third auxiliary electrode is arranged above the first auxiliary electrode and the second auxiliary electrode. The third auxiliary electrode covers and connects the first auxiliary electrode and the second auxiliary electrode. Since the second cathode is in contact with the third auxiliary electrode, and the first cathode is connected with the second cathode, the electrical connection between the first cathode, the first auxiliary electrode, the second auxiliary electrode, and the third auxiliary electrode can be realized, which can alleviate the problem of uneven display brightness in different regions on the OLED display panel caused by the large impedance of the first cathode. The OLED display panel of the embodiment of the present application does not need to use a mask when preparing the first light-emitting layer and the second light-emitting layer, so the manufacturing cost of the OLED display panel can be reduced. In the embodiment of the present application, the first auxiliary electrode and the second auxiliary electrode and the third auxiliary electrode covering the first auxiliary electrode and the second auxiliary electrode are arranged at intervals, so that when the part of the passivation layer around the first through hole is etched, the maximum expansion range of the width and depth of the first through hole is limited, and an undercut structure with a controllable etching range is formed to prevent the collapse of the passivation layer caused by too deep and too wide etching. Since the aperture of at least one end of the first through hole close to the third auxiliary electrode is enlarged after etching, when the conductive material is deposited to prepare the first cathode and the second cathode, the conductive material is thereby diffused in the portion of the first through hole where the aperture is enlarged, so that the prepared second cathode covers the second light-emitting layer and is in contact with the third auxiliary electrode, thereby realizing the electrical connection between the second cathode and the third auxiliary electrode. It is appreciated that since the first auxiliary electrode and the second auxiliary electrode are arranged at intervals, so that, in the interval area between the first auxiliary electrode and the second auxiliary electrode, since there are no obstacles at opposite ends of the interval area, an undercut phenomenon will not occur in the etching of a hole wall of the first through hole. After etching, the hole walls on the opposite sides of the first through hole facing the opposite ends of the interval area respectively have a shape of a taper, so that the second cathode can extend along the taper to connected to the first cathode.

### BRIEF DESCRIPTION OF DRAWINGS

### Description of Drawings

In order to more clearly illustrate the technical solutions of the embodiments of the application, the drawings illustrating the embodiments will be briefly described below. Obviously, the drawings in the following description merely illustrate some embodiments of the present invention. Other drawings may also be obtained by those skilled in the art according to these figures without paying creative work.

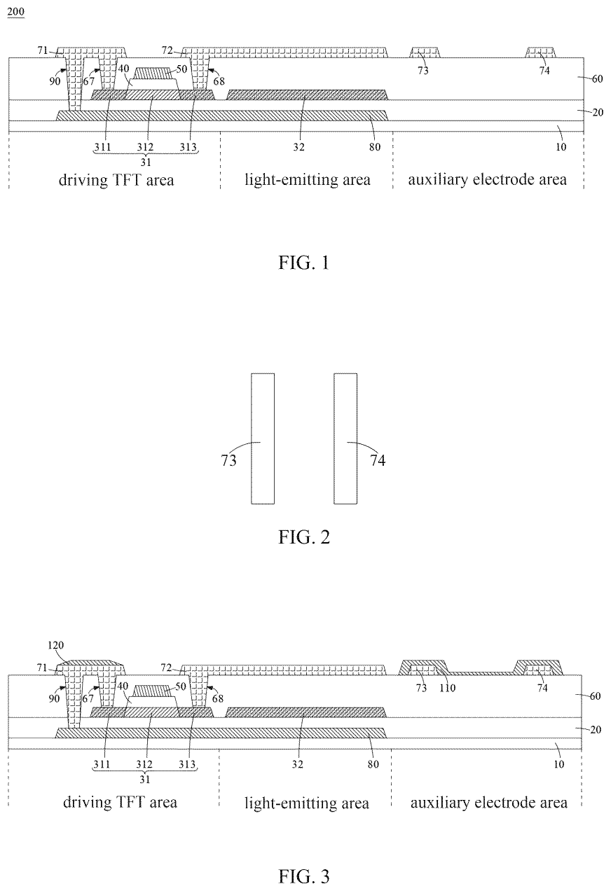

FIG. 1 is a schematic diagram of step 100 of a method of manufacturing an OLED display panel provided by an embodiment of the present application.

FIG. 2 is a schematic top view of a first auxiliary electrode and a second auxiliary electrode according to an embodiment of the present application.

FIG. 3 is a schematic diagram of step 200 of the method of manufacturing the OLED display panel provided by an embodiment of the present application.

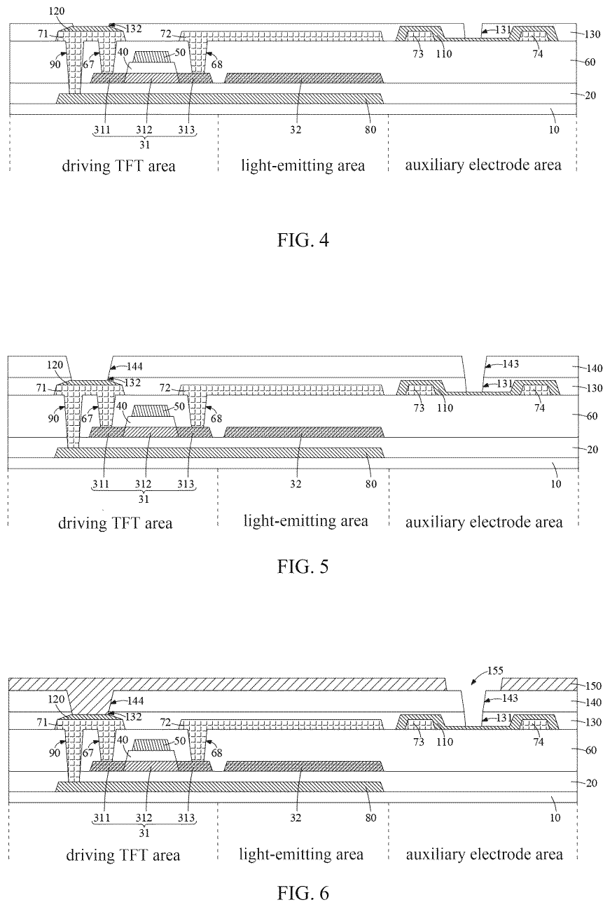

FIG. 4 is a schematic diagram of step 300 of the method of manufacturing the OLED display panel provided by an embodiment of the present application.

FIG. 5 is a schematic diagram of step 400 of the method of manufacturing the OLED display panel provided by an embodiment of the present application.

FIG. 6 is a schematic diagram of step 500 of the method of manufacturing the OLED display panel provided by an embodiment of the present application.

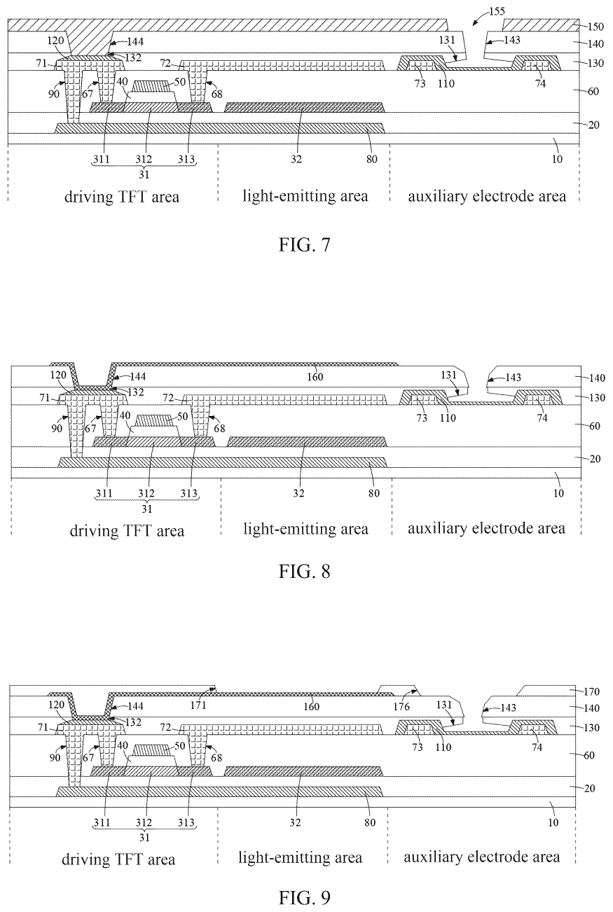

FIG. 7 is a schematic diagram of step 600 of the method of manufacturing the OLED display panel provided by an embodiment of the present application.

FIG. 8 is a schematic diagram of step 700 of the method of manufacturing the OLED display panel provided by an embodiment of the present application.

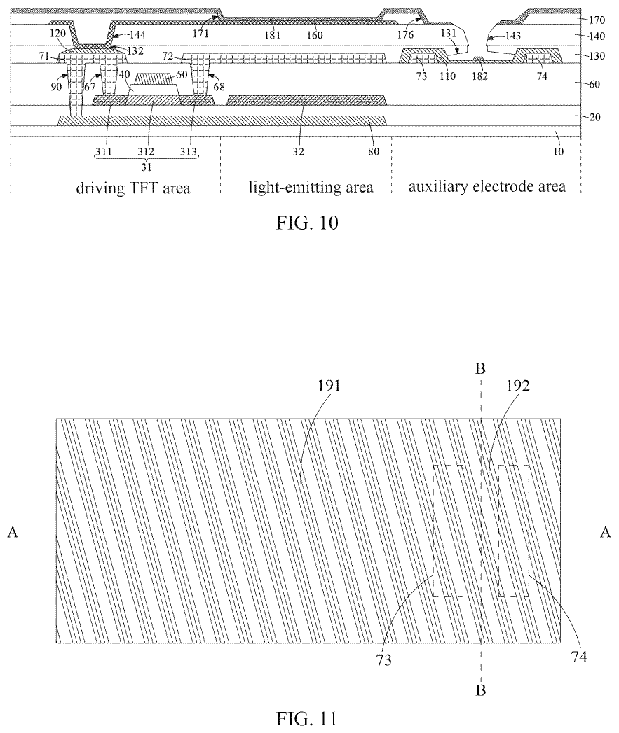

FIG. 9 is a schematic diagram of step 800 of the method of manufacturing the OLED display panel provided by an embodiment of the present application.

FIG. 10 is a schematic diagram of step 900 of the method of manufacturing the OLED display panel provided by an embodiment of the present application.

FIG. 11 is a schematic top view of an OLED display panel provided by an embodiment of the present application.

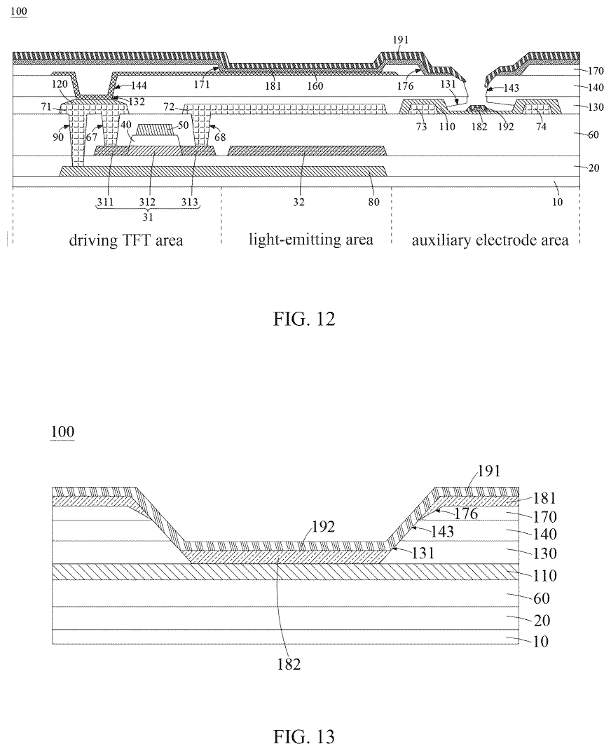

FIG. 12 is a schematic cross-sectional view of the OLED display panel shown in FIG. 11 taken along the direction A-A.

FIG. 13 is a schematic cross-sectional view of the OLED display panel shown in FIG. 11 taken along the direction B-B.

### EMBODIMENTS OF INVENTION

### Description of Embodiments of Invention

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

Referring to FIGS. 1 to 13, an embodiment of the present application provides a method of manufacturing an OLED display panel, including:

S100, referring to FIG. 1, providing a thin film transistor (TFT) backplane 200, wherein a topmost structural layer in the TFT backplane 200 is a source-drain layer, and the source-drain layer includes a source electrode 71, a drain electrode 72, a first auxiliary electrode 73, and a second auxiliary electrode 74 arranged at intervals.

Referring to FIG. 2, FIG. 2 is a schematic top view of the first auxiliary electrode and the second auxiliary electrode according to an embodiment of the present application. The first auxiliary electrode 73 and the second auxiliary electrode 74 may be parallel to each other. In other embodiments, the first auxiliary electrode 73 and the second auxiliary electrode 74 may not be parallel.

Exemplarily, the first auxiliary electrode 73 and the second auxiliary electrode 74 may be each independently linear, curved, folded, irregular-shaped, or the like.

Referring to FIG. 1, the TFT backplane 200 may include a base substrate 10, a buffer layer 20, a semiconductor layer, a gate insulating layer 40, a gate electrode 50, an interlayer dielectric layer 60 and a source-drain layer, which are stacked in sequence, wherein, the semiconductor layer includes an active layer 31, the active layer 31 is disposed corresponding to the gate 50, the active layer 31 includes a channel region 312 and a source contact region 311 and a drain contact region 313 disposed on opposite sides of the channel region 312, the interlayer dielectric layer 60 is provided with a seventh through hole 67 and an eighth through hole 68, the source electrode 71 is connected to the source contact region 311 of the active layer 31 through the seventh through hole 67, and the drain electrode 72 is connected to the drain contact region 313 of the active layer 31 through the eighth through hole 68.

As shown in FIG. 1, in some embodiments, the thin film transistor (TFT) in the TFT backplane 200 may be a top-gate TFT. It is appreciated that in other embodiments, the TFT in the TFT backplane 200 can also be a bottom-gate TFT.

Referring to FIG. 1, the semiconductor layer may further include a first storage capacitor electrode 32 arranged spaced apart from the active layer 31; a light-shielding layer 80 is provided between the base substrate 10 and the buffer layer 20, the light-shielding layer 80 is disposed corresponding to the active layer 31 and the first storage capacitor electrodes 32, and a storage capacitor is formed between the light-shielding layer 80 and the first storage capacitor electrodes 32.

Exemplarily, the base substrate 10 may be a rigid substrate or a flexible substrate, a material of the rigid substrate may be glass, and a material of the flexible substrate may be a polymer (e.g., polyimide, etc.).

Exemplarily, a material of the buffer layer 20, a material of the gate insulating layer 40, and a material of the interlayer dielectric layer 60 may be each independently selected from one or more of silicon nitride (SiNx), silicon oxide (SiOx), and silicon oxynitride (SiOxNy).

In some embodiments, a material of the semiconductor layer may be an oxide semiconductor material, such as indium zinc oxide (IZO), gallium indium oxide (IGO), indium gallium zinc oxide (IGZO), indium gallium tin oxide (IGTO), indium gallium zinc tin oxide (IGZTO), etc. In other embodiments, the material of the semiconductor layer may also be amorphous silicon, monocrystalline silicon, low temperature polycrystalline silicon, or the like.

Exemplarily, the source contact region 311, the drain contact region 313, and the first storage capacitor electrode 32 of the active layer 31 are all ion-doped regions with conductor properties; and the channel region 312 is a non-doped region with semiconductor properties.

Exemplarily, a material of the gate 50 and a material of the source-drain layer may be independently selected from one or more of metals, alloys, and metal nitrides, such as aluminum (Al), silver (Ag), tungsten (W), copper (Cu), nickel (Ni), chromium (Cr), molybdenum (Mo), titanium (Ti), platinum (Pt), tantalum (Ta) and neodymium (Nd) and the like, or alloys or nitrides of the above metals, and these materials can be used alone or in combination.

S200, referring to FIG. 3, forming a first conductive layer on the TFT backplane 200, wherein the first conductive layer includes a third auxiliary electrode 110, and the third auxiliary electrode 110 covers the first auxiliary electrode 73 and the second auxiliary electrode 74, and electrically connects the first auxiliary electrode 73 to the second auxiliary electrode 74.

Referring to FIG. 3, the first conductive layer may further include a protective layer 120 spaced apart from the third auxiliary electrode 110, the protective layer 120 is disposed above the source electrode 71, and the protective layer 120 is electrically connected to the source electrode 71. The protective layer 120 can improve the corrosion resistance of the source electrode 71 and prevent the surface of the source electrode 71 from being corroded during the subsequent process of etching the passivation layer 130 to form the second through hole 132.

Exemplarily, a material of the first conductive layer may be selected from one or more of metals, alloys, and metal nitrides, such as aluminum (Al), silver (Ag), tungsten (W), copper (Cu), nickel (Ni), chromium (Cr), molybdenum (Mo), titanium (Ti), platinum (Pt), tantalum (Ta), neodymium (Nd) and the like, or alloys or nitrides of the above metals, and these materials can be used alone or used in combination.

S300, referring to FIG. 4, forming a passivation layer 130 on the TFT backplane 200 to cover the source-drain layer and the first conductive layer, and forming a first through hole 131 and a second through hole 132 in the passivation layer 130, wherein the first through hole 131 is defined corresponding to an interval area between the first auxiliary electrode 73 and the second auxiliary electrode 74, and the second through hole 132 is defined corresponding to the source electrode 71.

Exemplarily, a material of the passivation layer 130 may be selected from one or more of silicon nitride (SiNx), silicon oxide (SiOx), and silicon oxynitride (SiOxNy).

S400, referring to FIG. 5, forming a planarization layer 140 on a side of the passivation layer away 130 from the TFT backplane 200, and forming a third through hole 143 and a fourth through hole 144 in the planarization layer 140. The third through hole 143 is communicated with the first through hole 131, and the fourth through hole 144 is communicated with the second through hole 132.

In some embodiments, a material of the planarization layer 140 may be an organic material; in other embodiments, the planarization layer 140 is a composite layer formed by alternately stacking organic material layers and inorganic material layers.

S500, referring to FIG. 6, forming a photoresist layer 150 on the planarization layer 140, and forming a fifth through hole 155 in the photoresist layer 150, wherein the fifth through hole 155 is communicated with the third through hole 143.

Exemplarily, the fifth through holes 155 may be formed on the photoresist layer 150 by exposure and development.

Referring to FIG. 6, the cross-sectional area of the fifth through hole 155 may be larger than that of the third through hole 143, so that the etching solution can more easily enter the third through hole 143 and then enter the first through hole 141 in the subsequent step S600.

S600, referring to FIG. 7, providing an etchant entering the first through hole 131 through the fifth through hole 155 and the third through hole 143, to etch a portion of the passivation layer 130 around the first through hole 131, so that an aperture of at least one end of the first through hole 131 that is close to the third auxiliary electrode 110 is enlarged, and in a direction from the first auxiliary electrode 73 to the second auxiliary electrode 74, the at least one end of the first through hole 131 that is close to the third auxiliary electrode 110 has a width greater than a width of the third through hole 143.

It should be noted that, since the first auxiliary electrode 73 and the second auxiliary electrode 74 are arranged at intervals, the first through hole 131 generally has two sides facing the first auxiliary electrode 73 and the second auxiliary electrode 74 and two sides facing the opposite sides of the opposite ends of the interval area between the first auxiliary electrode 73 and the second auxiliary electrode 74, respectively. Because the first auxiliary electrode 73 and the second auxiliary electrode 74 are in the shape of strip protrusions, the range in which the hole wall of the first through hole 131 extends toward the first auxiliary electrode 73 and the second auxiliary electrode 74 respectively during etching is limited, thus forming an undercut structure. In the interval area between the first auxiliary electrode 73 and the second auxiliary electrode 74, since the opposite ends of the interval area are not provided with obstacles such as the first auxiliary electrode 73 and the second auxiliary electrode 74, the etching of the hole wall of the first through hole 131 will not cause an undercut structure, but a shape of a taper is formed according to a normal etching process.

As shown in FIG. 7, in some embodiments, only the aperture of one end of the first through hole 131 close to the third auxiliary electrode 110 is enlarged, and the aperture of the end of the first through hole 131 close to the planarization layer 140 remains unchanged or changes less. In other embodiments, the aperture of the first through hole 131 from the end close to the third auxiliary electrode 110 to the end close to the planarization layer 140 may be enlarged.

It is appreciated that, in the embodiment of the present application, the first auxiliary electrode 73 and the second auxiliary electrode 74 arranged at intervals and the third auxiliary electrode 110 covering the first auxiliary electrode 73 and the second auxiliary electrode 74 are arranged, so that when the portion of the passivation layer 130 around the first through hole 131 is etched, the maximum expansion range of the first through hole 131 in terms of width and depth is limited, and an undercut structure with a controllable etching range is formed to prevent the etching from being too deep and too wide to result in collapse of the passivation layer 130.

S700, referring to FIG. 8, the photoresist layer 150 is removed, an anode 160 is disposed on the planarization layer 140, and the anode 160 is electrically connected to the source electrode 71 through the fourth through hole 144 and the second through hole 132.

Exemplarily, when the first conductive layer further includes the protective layer 120 spaced apart from the third auxiliary electrode 110, the anode 160 is electrically connected to the side of the protective layer 120 away from the source electrode 71. The side of the protective layer 120 away from the anode 160 is electrically connected to the source electrode 71, so the electrical connection between the anode 160 and the source electrode 71 can be realized.

S800, referring to FIG. 9, a pixel definition layer 170 covering the anode 160 is disposed on the planarization layer 140, an opening 171 and a sixth through hole 176 are formed on the pixel definition layer 170, and the sixth through hole 176 corresponds to the third through hole 143. The opening 171 exposes the anode 160.

Referring to FIG. 9, the cross-sectional area of the sixth through hole 176 can be larger than that of the third through hole 143 to facilitate subsequent deposition of conductive materials, which can make it easier for the conductive material to enter the third through hole 143 and then pass through the first through hole 131. Exemplarily, in the direction from the first auxiliary electrode 73 to the second auxiliary electrode 74, the width of the sixth through hole 176 may be greater than the width of the third through hole 143. It should be noted that, in the embodiments of the present application, the cross-sectional area refers to the area of the cross-section obtained by cutting in a direction parallel to the base substrate 10.

Exemplarily, the material of the anode 160 may be a transparent conductive metal oxide, such as indium tin oxide (ITO, Indium tin oxide).

S900, referring to FIG. 10, a luminescent material is deposited on the side of the TFT backplane 200 where the pixel definition layer 170 is provided, and the luminescent material deposited on the pixel definition layer 170 forms the first light emitting layer 181, and the luminescent material passing through the sixth through hole and deposited on the third auxiliary electrode 110 forms the second luminescent layer 182, wherein the portion of the first luminescent layer 181 corresponding to the opening 171 covers the anode 160.

Exemplarily, the luminescent material may be deposited on the side of the TFT backplane 200 on which the pixel defining layer 170 is provided by means of evaporation or inkjet printing.

It should be noted that, in the embodiment of the present application, a mask is not required when preparing the first light-emitting layer 181 and the second light-emitting layer 182, so the manufacturing cost of the OLED display panel 100 can be reduced.

S1000, referring to FIG. 11 to FIG. 13, a conductive material is deposited on the side of the TFT backplane 200 where the first light-emitting layer 181 is disposed, and the conductive material deposited on the first light-emitting layer 181 forms a first cathode 191, and the conductive material deposited on the second light emitting layer 182 forms a second cathode 192, the first cathode 191 is connected to the second cathode 192, and the second cathode 192 covers the second light emitting layer 182 and is in contact with the third auxiliary electrode 110.

Exemplarily, the conductive material may be deposited on the side of the TFT backplane 200 on which the first light-emitting layer 181 is provided by means of evaporation or sputtering.

Exemplarily, the material of the cathode may be a metal or alloy, such as silver or a magnesium-silver alloy. It is appreciated that the cathode has a light transmittance property, so that the light emitted by the light emitting layer can be emitted through the cathode, that is to say, the OLED display panel 100 provided by the embodiment of the present application is a top emission type OLED display panel. Exemplarily, the light transmittance of the cathode is above 30%, such as 30%, 40%, 50%, 60%, 70%, 80%, 90%, 95%, 99%, and the like.

FIG. 11 is a schematic top view of an OLED display panel according to an embodiment of the present application, FIG. 12 is a schematic cross-sectional view of the OLED display panel shown in FIG. 11 in the direction AA, and FIG. 13 is a schematic diagram of the OLED display panel shown in FIG. 11 in the direction BB. From FIGS. 11 to 13, it can be seen that the AA direction is the direction from the first auxiliary electrode 73 to the second auxiliary electrode 74, and the BB direction and the AA direction are perpendicular to each other, that is, the BB direction is the direction from the first auxiliary electrode 73 to the second auxiliary electrode 74. The directions of the two auxiliary electrodes 74 are perpendicular to each other. Since FIG. 13 is a schematic cross-sectional view obtained by cutting the OLED display panel 100 along the BB direction in the interval area between the first auxiliary electrode 73 and the second auxiliary electrode 74, it can be seen that in the BB direction, the hole wall of the first through hole 131 exhibits a shape of a taper, so that the second cathode 192 can extend along the taper to be connected with the first cathode 191.

Referring to FIG. 12, a driving TFT area, a light-emitting area and an auxiliary electrode area can be defined on the OLED display panel 100. The source electrode 71, the drain electrode 72, the gate electrode 50 and the active layer 31 are all arranged in the driving TFT area. The opening 171 on the definition layer 170 and the first storage capacitor electrode 32 are all disposed in the light emitting region, and the first auxiliary electrode 73, the second auxiliary electrode 74 and the third auxiliary electrode 110 are all disposed in the auxiliary electrode region.

It is appreciated that a TFT device is arranged in the driving TFT region, and the light-emitting layer in the light-emitting region can emit light under the driving of the voltage between the anode 160 and the first cathode 191, so that the OLED display panel 100 can display a picture. The first auxiliary electrode 73, the second auxiliary electrode 74 and the third auxiliary electrode 110 are arranged in the auxiliary electrode area, which can reduce the impedance of the first cathode 191, so that the display brightness of different areas on the OLED display panel 100 is uniform, and the image uniformity is improved.

Exemplarily, the interlayer dielectric layer 60 and the buffer layer 20 are provided with a ninth through hole 90, and the source electrode 71 is connected to the light-shielding layer 80 through the ninth through hole 90, which can improve the electrical performance of the TFT and make the channel current more stable

To sum up, in the method of manufacturing the OLED display panel provided by the embodiment of the present application, the first auxiliary electrode 73 and the second auxiliary electrode 74 arranged at intervals are arranged in the source-drain layer, and the first auxiliary electrode 73 and the second auxiliary electrode 74 are arranged in the source-drain layer. A third auxiliary electrode 110 is arranged above the second auxiliary electrodes 74, and the first auxiliary electrode 73 and the second auxiliary electrode 74 are covered and connected by the third auxiliary electrode 110. After the first cathode 191 and the second cathode 192 are subsequently prepared, since the second cathode 192 is in contact with the third auxiliary electrode 110, and the first cathode 191 is connected with the second cathode 192, the electrical connection between the first cathode 191 and the first auxiliary electrode 73, the second auxiliary electrode 74 and the third auxiliary electrode 110 can be realized, and he problem of uneven display brightness in different regions on the OLED display panel 100 caused by the large impedance of the first cathode 191 can be alleviated. The embodiment of the present application does not need to use a mask when preparing the first light-emitting layer 181 and the second light-emitting layer 182, so the production cost of the OLED display panel 100 can be reduced. In the embodiment of the present application, the first auxiliary electrode 73 and the second auxiliary electrode 74 arranged at intervals and the third auxiliary electrode 110 covering the first auxiliary electrode 73 and the second auxiliary electrode 74 are arranged, so that the first auxiliary electrode 73 and the second auxiliary electrode 74 are arranged on the opposite passivation layer 130. When the portion of the passivation layer 130 around the first through hole 131 is etched, the maximum expansion range of the first through hole 131 in terms of width and depth is limited, and an undercut structure with a controllable etching range is formed, so as to prevent collapse of the passivation layer 130 caused by too deep and too wide etching. Since the aperture of at least one end of the first through hole 131 close to the third auxiliary electrode 110 is enlarged after etching, when the conductive material is deposited to prepare the first cathode 191 and the second cathode 192, the conductive material can diffuses in the portion of the first through hole 131 where the aperture is enlarged, so that the prepared second cathode 192 covers the second light-emitting layer 182 and contacts the third auxiliary electrode 110, thereby realizing the electrical connection between the second cathode 192 and the third auxiliary electrode 110. It is appreciated that since the first auxiliary electrode 73 and the second auxiliary electrode 74 are arranged at intervals, in the interval area between the first auxiliary electrode 73 and the second auxiliary electrode 74, since there are no obstacles at opposite ends of the interval area, Therefore, the etching of the hole wall of the first through hole 131 will not cause an undercut phenomenon. After etching, the hole walls on the opposite sides of the first through hole 131 facing the opposite ends of the interval area respectively present a shape of a taper, so that the second cathode 192 may extend along the taper to connect to the first cathode 191.

Referring to FIG. 12 and FIG. 13, an embodiment of the present application further provides an OLED display panel 100, which can be manufactured by the method of manufacturing the OLED display panel in any of the above-mentioned embodiments. The OLED display panel 100 may include a TFT backplane 200, a first conductive layer, a passivation layer 130, a planarization layer 140, an anode 160, a pixel definition layer 170, a first light-emitting layer 181, a second light-emitting layer 182, a first cathode 191, and a second cathode 192.

The topmost structural layer in the TFT backplane 200 is a source-drain layer, and the source-drain layer includes a source electrode 71, a drain electrode 72, a first auxiliary electrode 73, and a second auxiliary electrode 74 arranged at intervals.

The first conductive layer is disposed on the TFT backplane 200, the first conductive layer includes a third auxiliary electrode 110, the third auxiliary electrode 110 covers the first auxiliary electrode 73 and the second auxiliary electrode 74, and the first auxiliary electrode 73 is electrically connected to the second auxiliary electrode 74.

The passivation layer 130 is disposed on the TFT backplane 200 and covers the source-drain layer and the first conductive layer. The passivation layer 130 is provided with a first through hole 131 and a second through hole 132. The first through hole 131 is provided corresponding to an interval area between the auxiliary electrode 73 and the second auxiliary electrode 74, and the second through hole 132 is provided corresponding to the source electrode 71.

The planarization layer 140 is disposed on a side of the passivation layer 130 away from the TFT backplane 200, and a third through hole 143 and a fourth through hole 144 are formed in the planarization layer 140, the third through hole 143 is communicated with the first through hole 131, and the fourth through hole 144 is communicated with the second through hole 132. In a direction from the first auxiliary electrode 73 to the second auxiliary electrode 74, a width of at least one end of the first through hole 131 close to the third auxiliary electrode 110 is greater than a width of the third through hole 143.

The anode 160 is disposed on the planarization layer 140, and the anode 160 is electrically connected to the source electrode 71 through the fourth through hole 144 and the second through hole 132.

The pixel definition layer 170 is disposed on the planarization layer 140, the pixel definition layer 170 is provided with an opening 171 and a sixth through hole 176, the sixth through hole 176 is disposed corresponding to the third through hole 143, and the opening 171 exposes the anode 160.

The first light-emitting layer 181 is disposed on the pixel definition layer 170; a portion of the first light-emitting layer 181 corresponding to the opening 171 covers the anode 160; and the second light-emitting layer 182 is disposed on the third auxiliary electrode 110.

The first cathode 191 is disposed on the first light-emitting layer 181; the second cathode 192 is disposed on the second light-emitting layer 182, the first cathode 191 is connected to the second cathode 192, and the second cathode 192 covers the second light-emitting layer 182 and is in contact with the third auxiliary electrode 110.

Referring to FIG. 2, the first auxiliary electrode 73 and the second auxiliary electrode 74 may be parallel to each other.

Referring to FIG. 9, the cross-sectional area of the sixth through hole 176 can be larger than that of the third through hole 143 to facilitate subsequent deposition of conductive materials, which can make it easier for the conductive material to enter the third through hole 143 and then pass through the first through hole 131. Exemplarily, in the direction from the first auxiliary electrode 73 to the second auxiliary electrode 74, the width of the sixth through hole 176 may be greater than the width of the third through hole 143. Referring to FIG. 12, the first conductive layer may further include a protective layer 120 spaced apart from the third auxiliary electrode 110, the protective layer 120 is disposed above the source electrode 71, and the opposite sides of the protective layer 120 are respectively electrically connected to the source electrode 71 and the anode 160.

Referring to FIG. 12, the TFT backplane 200 may include a base substrate 10, a buffer layer 20, a semiconductor layer, a gate insulating layer 40, a gate electrode 50, an interlayer dielectric layer 60 and a source-drain layer, which are stacked in sequence, wherein, the semiconductor layer includes an active layer 31, the active layer 31 is disposed corresponding to the gate 50, the active layer 31 includes a channel region 312 and a source contact region 311 and a drain contact region 313 disposed on opposite sides of the channel region 312, the interlayer dielectric layer 60 is provided with a seventh through hole 67 and an eighth through hole 68, the source electrode 71 is connected to the source contact region 311 of the active layer 31 through the seventh through hole 67, and the drain electrode 72 is connected to the drain contact region 313 of the active layer 31 through the eighth through hole 68.

Referring to FIG. 12, the semiconductor layer may further include a first storage capacitor electrode 32 arranged spaced apart from the active layer 31; a light-shielding layer 80 is provided between the base substrate 10 and the buffer layer 20, the light-shielding layer 80 is disposed corresponding to the active layer 31 and the first storage capacitor electrodes 32, and a storage capacitor is formed between the light-shielding layer 80 and the first storage capacitor electrodes 32.

Referring to FIG. 12, a driving TFT area, a light-emitting area and an auxiliary electrode area can be defined on the OLED display panel 100. The source electrode 71, the drain electrode 72, the gate electrode 50 and the active layer 31 are all arranged in the driving TFT area. The opening 171 on the definition layer 170 and the first storage capacitor electrode 32 are all disposed in the light emitting region, and the first auxiliary electrode 73, the second auxiliary electrode 74 and the third auxiliary electrode 110 are all disposed in the auxiliary electrode region.

The OLED display panel and the manufacturing method thereof provided by the embodiments of the present application are described in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

What is claimed is:

1. An organic light-emitting diode (OLED) display panel, comprising:
a thin film transistor (TFT) backplane, wherein a topmost structural layer in the TFT backplane is a source-drain layer, and the source-drain layer comprises a source electrode, a drain electrode, a first auxiliary electrode, and a second auxiliary electrode arranged at intervals;
a first conductive layer disposed on the TFT backplane, wherein the first conductive layer comprises a third auxiliary electrode, and the third auxiliary electrode covers the first auxiliary electrode and the second auxiliary electrode, and electrically connects the first auxiliary electrode to the second auxiliary electrode;
a passivation layer disposed on the TFT backplane and covering the source-drain layer and the first conductive layer, wherein the passivation layer is provided with a first through hole and a second through hole, the first through hole is defined corresponding to an interval area between the first auxiliary electrode and the second auxiliary electrode, and the second through hole is defined corresponding to the source electrode;
a planarization layer arranged on a side of the passivation layer away from the TFT backplane, wherein a third through hole and a fourth through hole are defined in the planarization layer, the third through hole is communicated with the first through hole, the fourth through hole is communicated with the second through hole, and in a direction from the first auxiliary electrode to the second auxiliary electrode, at least one end of the first through hole that is close to the third auxiliary electrode has a width greater than a width of the third through hole;
an anode disposed on the planarization layer, wherein the anode is electrically connected to the source electrode through the fourth through hole and the second through hole;
a pixel definition layer disposed on the planarization layer, wherein the pixel definition layer is provided with an opening and a sixth through hole, the sixth through hole is arranged corresponding to the third through hole, and the opening exposes an anode;
a first light-emitting layer disposed on the pixel definition layer, wherein a portion of the first light-emitting layer corresponding to the opening covers the anode;
a second light-emitting layer disposed on the third auxiliary electrode;
a first cathode disposed on the first light-emitting layer; and
a second cathode disposed on the second light-emitting layer, wherein the first cathode is connected to the second cathode, and the second cathode covers the second light-emitting layer and is in contact with the third auxiliary electrode.

2. The OLED display panel according to claim 1, wherein the first auxiliary electrode and the second auxiliary electrode are parallel to each other.

3. The OLED display panel according to claim 1, wherein the first auxiliary electrode is not parallel to the second auxiliary electrode.

4. The OLED display panel according to claim 1, wherein the first auxiliary electrode and the second auxiliary electrode are each independently linear, curved, or folded.

5. The OLED display panel according to claim 1, wherein a cross-sectional area of the sixth through hole is larger than a cross-sectional area of the third through hole.

6. The OLED display panel according to claim 1, wherein the first conductive layer further comprises a protective layer spaced apart from the third auxiliary electrode, the protective layer is arranged above the source electrode, and opposite sides of the protective layer are respectively electrically connected to the source electrode and the anode electrode.

7. The OLED display panel according to claim 1, wherein a material of the first conductive layer comprises one or more of a metal, an alloy, and metal nitride.

8. The OLED display panel according to claim 1, wherein the TFT backplane comprises a base substrate, a buffer layer, a semiconductor layer, a gate insulating layer, a gate electrode, an interlayer dielectric layer, and the source-drain layer which are stacked in sequence, wherein the semiconductor layer comprises an active layer, the active layer is disposed corresponding to the gate electrode, the active layer comprises a channel region and a source electrode and a drain contact region disposed on opposite sides of the channel region, the interlayer dielectric layer is provided with a seventh through hole and an eighth through hole, the source electrode is connected to the source contact region of the active layer through the seventh through hole, and the drain is connected to the drain contact region of the active layer through the eighth through hole.

9. The OLED display panel according to claim 8, wherein the semiconductor layer further comprises a first storage capacitor electrode spaced apart from the active layer; and a light-shielding layer is disposed between the base substrate and the buffer layer, the light-shielding layer is disposed corresponding to the active layer and the first storage capacitor electrode, and a storage capacitor is formed between the light-shielding layer and the first storage capacitor electrode.

10. The OLED display panel according to claim 9, wherein a driving TFT area, a light-emitting area, and an auxiliary electrode area are defined on the OLED display panel, wherein the source electrode, the drain electrode, and the gate electrode, the active layer are all arranged in the driving TFT area; the opening of the pixel definition layer and the first storage capacitor electrode are both arranged in the light-emitting area; and the first auxiliary electrode, the second auxiliary electrode, and the third auxiliary electrode are all disposed in the auxiliary electrode region.

11. A method of manufacturing an organic light-emitting diode (OLED) display panel, comprising:
providing a thin film transistor (TFT) backplane, wherein a topmost structural layer in the TFT backplane is a source-drain layer, and the source-drain layer comprises a source electrode, a drain electrode, a first auxiliary electrode, and a second auxiliary electrode arranged at intervals;
forming a first conductive layer on the TFT backplane, wherein the first conductive layer comprises a third auxiliary electrode, and the third auxiliary electrode covers the first auxiliary electrode and the second auxiliary electrode, and electrically connects the first auxiliary electrode to the second auxiliary electrode;
forming a passivation layer on the TFT backplane to cover the source-drain layer and the first conductive layer, and forming a first through hole and a second through hole in the passivation layer, wherein the first through hole is defined corresponding to an interval area between the first auxiliary electrode and the second auxiliary electrode, and the second through hole is defined corresponding to the source electrode;
forming a planarization layer on a side of the passivation layer away from the TFT backplane, and forming a third through hole and a fourth through hole in the planarization layer, wherein the third through hole is communicated with the first through hole, and the fourth through hole is communicated with the second through hole;
forming a photoresist layer on the planarization layer, and forming a fifth through hole in the photoresist layer, wherein the fifth through hole is communicated with the third through hole;
providing an etchant entering the first through hole through the fifth through hole and the third through hole, to etch a portion of the passivation layer around the first through hole, so that an aperture of at least one end of the first through hole that is close to the third auxiliary electrode is enlarged, and in a direction from the first auxiliary electrode to the second auxiliary electrode, the at least one end of the first through hole that is close to the third auxiliary electrode has a width greater than a width of the third through hole;
removing the photoresist layer, and forming an anode on the planarization layer, wherein the anode is electrically connected to the source electrode through the fourth through hole and the second through hole;
forming a pixel definition layer on the planarization layer to cover the anode, and forming an opening and a sixth through hole in the pixel definition layer, wherein the sixth through hole is disposed corresponding to the third through hole, and the opening exposes the anode;
depositing a luminescent material on a side of the TFT backplane on which the pixel defining layer is disposed, wherein the luminescent material deposited on the pixel defining layer forms a first light-emitting layer, the light-emitting material passing through the sixth through hole and the third through hole to deposit on the third auxiliary electrode forms a second light-emitting layer, and a portion of the first light-emitting layer corresponding to the opening covers the anode; and
depositing a conductive material on a side of the TFT backplane on which the first light-emitting layer is disposed, wherein the conductive material deposited on the first light-emitting layer forms a first cathode, the conductive material deposited on the second light-emitting layer forms a second cathode, the first cathode is connected to the second cathode, and the second cathode covers the second light-emitting layer and is in contact with the third auxiliary electrode.

12. The method of manufacturing an OLED display panel according to claim 11, wherein the first auxiliary electrode and the second auxiliary electrode are parallel to each other.

13. The method of manufacturing an OLED display panel according to claim 11, wherein the first auxiliary electrode and the second auxiliary electrode are not parallel.

14. The method of manufacturing an OLED display panel according to claim 11, wherein each of the first auxiliary electrode and the second auxiliary electrode is independently linear, curved, or folded.

15. The method of manufacturing an OLED display panel according to claim 11, wherein a cross-sectional area of the sixth through hole is larger than a cross-sectional area of the third through hole.

16. The method of manufacturing an OLED display panel according to claim 11, wherein the first conductive layer further comprises a protective layer spaced apart from the third auxiliary electrode, the protective layer is arranged above the source electrode, and the protective layer is electrically connected to the source electrode; and
the anode is electrically connected to a side of the protective layer away from the source electrode after the anode is disposed on the planarization layer.

17. The method of manufacturing an OLED display panel according to claim 11, wherein a material of the first conductive layer comprises one or more of a metal, an alloy, and metal nitride.

18. The method of manufacturing an OLED display panel according to claim 11, wherein the TFT backplane comprises a base substrate, a buffer layer, a semiconductor layer, a gate insulating layer, a gate electrode, an interlayer dielectric layer, and the source-drain layer which are stacked in sequence, wherein the semiconductor layer comprises an active layer, the active layer is disposed corresponding to the gate electrode, the active layer comprises a channel region and a source electrode and a drain contact region disposed on opposite sides of the channel region, the interlayer dielectric layer is provided with a seventh through hole and an eighth through hole, the source electrode is connected to the source contact region of the active layer through the seventh through hole, and the drain is connected to the drain contact region of the active layer through the eighth through hole.

19. The method of manufacturing an OLED display panel according to claim 18, wherein the semiconductor layer further comprises a first storage capacitor electrode spaced apart from the active layer; a light-shielding layer is disposed between the base substrate and the buffer layer, the light-shielding layer is disposed corresponding to the active layer and the first storage capacitor electrode, and a storage capacitor is formed between the light-shielding layer and the first storage capacitor electrode.

20. The method of manufacturing an OLED display panel according to claim 19, wherein a driving TFT area, a light-emitting area, and an auxiliary electrode area are defined on the OLED display panel, wherein the source electrode, the drain electrode, and the gate electrode, the active layer are all arranged in the driving TFT area; the opening of the pixel definition layer and the first storage capacitor electrode are both arranged in the light-emitting area; and the first auxiliary electrode, the second auxiliary electrode, and the third auxiliary electrode are all disposed in the auxiliary electrode region.
